(19) United States
(12) Patent Application Publication
(10) Pub. No.: US 2008/0182354 A1
(43) Pub. Date: Jul. 31, 2008

(54) METHODS OF FABRICATING CMOS IMAGE SENSORS

(75) Inventors: Jong-Jin Lee, Seoul (KR); Ju-Hyun Ko, Gyeonggi-do (KR); Jong-Eun Park, Gyeonggi-do (KR); Hyun-Suk Kim, Seoul (KR); Dong-Yoon Jang, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/950,249

(22) Filed: Dec. 4, 2007

(30) Foreign Application Priority Data
Jan. 31, 2007 (KR) 10-2007-0010063

(51) Int. Cl. H01L 31/18

(52) U.S. Cl. 438/59; 257/E31.001

(57) ABSTRACT

CMOS image sensors and related methods of fabricating CMOS image sensors are disclosed. Fabrication of a CMOS image sensor can include forming a first impurity region having a first conductivity type in a semiconductor substrate. A second impurity region having a second conductivity type is formed in the semiconductor substrate adjacent to the first impurity region. A third impurity region having the first conductivity type is formed in the semiconductor substrate and located below the second impurity region. A transfer gate is formed on the semiconductor substrate and at least partially overlaps the first, second, and third impurity regions. A photo sensitive device is formed in the semiconductor substrate and adjacent to one side of the transfer gate. A floating diffusion region is formed in the semiconductor substrate and located adjacent to an opposite side of the transfer gate from the photosensitive device.

### CROSS-REFERENCE TO RELATED PATENT APPLICATION

This application claims priority under 35 U.S.C. §119 to Korean Patent Application No. 10-2007-0010063, filed on Jan. 31, 2007, in the Korean Intellectual Property Office, the disclosure of which is incorporated herein in its entirety by reference.

### FIELD OF THE INVENTION

The present invention relates to image sensors and their related fabrication, and more particularly to CMOS image sensors and their related fabrication.

### BACKGROUND OF THE INVENTION

Image sensors can be fabricated from semiconductor devices that are configured to convert incident light forming an optical image into an electrical signal(s). Two types of semiconductor image sensor devices are charge coupled devices (CCDs) and CMOS image sensors (CISs).

A unit pixel of a CMOS image sensor includes a transfer transistor, which transfers charges that are generated by a photo sensitive device (PSD) to a floating diffusion region within a silicon substrate. In the CMOS image sensor, so-called “dark current” may be caused by a trap action associated with a dangling bond at a hetero-interface between, for example, the silicon substrate and a silicon oxide layer thereon. The dangling bond can occur in the energy band between a valence band and a conduction band. The dangling bond may capture and shift electrons from the valence band to the conduction band regardless of whether sufficient light energy is incident upon the PSD. Such dark current due to shifted electrons can accumulate at the PSD and may cause spots, such as color spot(s) and/or white spot(s), to appear on a display screen. Such displayed spots may appear as noise on a display image and/or may appear as the image itself even when no such image is incident to the sensor.

Additionally, when the CMOS image sensor is subjected to an intensive light energy level, optical charges may accumulate that exceed the capacity of the PSD. These excess charges cannot be stored in the PSD and may consequently flow into an adjacent unit pixel, thereby causing an undesirable blooming effect.

### SUMMARY OF THE INVENTION

Some embodiments of the present invention provide CMOS image sensors and associated methods that may reduce/avoid occurrence of dark current or blooming effect. Some embodiments of the present invention provide CMOS image sensors that may reduce/avoid occurrence of both dark current and blooming effect.

According to some embodiments of the present invention, a CMOS image sensor includes a transfer gate, a photo sensitive device, a floating diffusion region, and first, second, and third impurity regions. The transfer gate is on a semiconductor substrate. The photosensitive device is in the semiconductor substrate adjacent to a side of the transfer gate. The floating diffusion region is in the semiconductor substrate adjacent to an opposite side of the transfer gate from the photosensitive device. The first impurity region has a first conductivity type, and is in the semiconductor substrate below the transfer gate and is adjacent to the photosensitive device. The second impurity region has a second conductivity type, and is in the semiconductor substrate located below the transfer gate and between the first impurity region and the floating diffusion region. The third impurity region has the first conductivity type, and is in the semiconductor substrate located below the second impurity region and the transfer gate, and is adjacent to the floating diffusion region.

In some further embodiments, the first conductivity type can be one of a P-type and an N-type and the second conductivity type is the other one of the P-type and the N-type. The first and second impurity regions can extend downward from an upper surface of the semiconductor substrate. The first impurity region can be spaced apart from the floating diffusion region, and the second and third impurity regions can be spaced apart from the photo sensitive device.

In some further embodiments, a fourth impurity region having the second conductivity type is below the first impurity region and the transfer gate, and is adjacent to the photo sensitive device. The fourth impurity region can be at the same depth in the semiconductor substrate as the third impurity region. The fourth impurity region can be spaced apart from the floating diffusion region, and the third impurity region can be between the fourth impurity region and the floating diffusion region.

In some other embodiments, a method of fabricating a CMOS image sensor includes forming a first impurity region having a first conductivity type in a semiconductor substrate. A second impurity region having a second conductivity type is formed in the semiconductor substrate adjacent to the first impurity region. A third impurity region having the first conductivity type is formed in the semiconductor substrate and located below the second impurity region. A transfer gate is formed on the semiconductor substrate and at least partially overlaps the first, second, and third impurity regions. A photo sensitive device is formed in the semiconductor substrate and adjacent to one side of the transfer gate. A floating diffusion region is formed in the semiconductor substrate and located adjacent to an opposite side of the transfer gate from the photosensitive device.

In some further embodiments, formation of the first, second, and third impurity regions include forming an ion implantation mask on an upper surface of the semiconductor substrate and having an opening that exposes a region of the semiconductor substrate in which the transfer gate will be formed. The first impurity region can be formed by implanting impurity ions having the first conductivity type into the semiconductor substrate at a first tilt angle through the opening in the ion implantation mask. The second impurity region can be formed by implanting impurity ions having the second conductivity type into the semiconductor substrate at a second tilt angle through the opening in the ion implantation mask. The third impurity region can be formed by implanting impurity ions having the first conductivity type into the semiconductor substrate below the second impurity region at the second tilt angle through the opening in the ion implantation mask.

In some further embodiments, the first tilt angle can be in a range between 10 degrees and 45 degrees with respect to the upper surface of the semiconductor substrate. The second tilt angle can be in a range between 135 degrees and 170 degrees with respect to the upper surface of the semiconductor substrate. Alternatively or additionally, the first and second tilt angles and a thickness of the ion implantation mask can be defined so that the first impurity region is formed adjacent to the second impurity region in the semiconductor substrate.

In some further embodiments, a fourth impurity region having the second conductivity type is formed below the first impurity region and the transfer gate and adjacent to the photo sensitive device. Formation of the fourth impurity region can include implanting impurity ions having the first conductivity type at a third tilt angle through the opening in the ion implantation mask into a region of the semiconductor substrate below the first impurity region. The third tilt angle can be in a range between 10 degrees and 45 degrees with respect to an upper surface of the semiconductor substrate. The fourth impurity region can be formed at the same depth in the semiconductor substrate as the third impurity region. The third impurity region can be formed between the fourth impurity region and the floating diffusion region.

In some other embodiments, a CMOS image sensor includes a transfer gate, a photo sensitive device, a floating diffusion region, and a first and second impurity region. The transfer gate is on a semiconductor substrate. The photo sensitive device is in the semiconductor substrate adjacent to a side of the transfer gate. The floating diffusion region is in the semiconductor substrate adjacent to an opposite side of the transfer gate from the photosensitive device. The first impurity region is in the semiconductor substrate and located below the transfer gate and adjacent to the photo sensitive device. The second impurity region is in the semiconductor substrate and located below the transfer gate and between the first impurity region and the floating diffusion region. The first impurity region and the second impurity region are configured to inhibit electron flow to the photo sensitive device through a channel region in the substrate under the transfer gate so as to reduce dark current from the CMOS image sensor.

### BRIEF DESCRIPTION OF THE DRAWINGS

The above and other features and potential advantages of the present invention will become more apparent in view of the following detailed exemplary embodiments thereof with reference to the attached drawings in which:

FIG. 1 is a circuit diagram of a unit pixel included in a CMOS image sensor according to some embodiments of the present invention;

FIG. 2 illustrates a layout of a unit pixel included in a CMOS image sensor according to some embodiments of the present invention;

FIGS. 3 and 4 are cross-sectional views of the unit pixel taken along the line III-III′ illustrated in FIG. 2; and

FIGS. 5 through 11 are cross-sectional views of sequential stages in some methods of fabricating a CMOS image sensor according to some embodiments of the present invention.

### DETAILED DESCRIPTION OF THE INVENTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first impurity region could be termed a second impurity region, and, similarly, a second impurity region could be termed a first impurity region without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Embodiments of the present invention may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

Furthermore, the words of the “first conductive type” and the “second conductive type” indicate conductive types opposite to each other such as P type or N type. Hereinafter, it is assumed that the first conductive type is P type and the second conductive type is N type, but the present invention is not restricted thereto. Accordingly, the below-described embodiments include an embodiment that is complementary thereto.

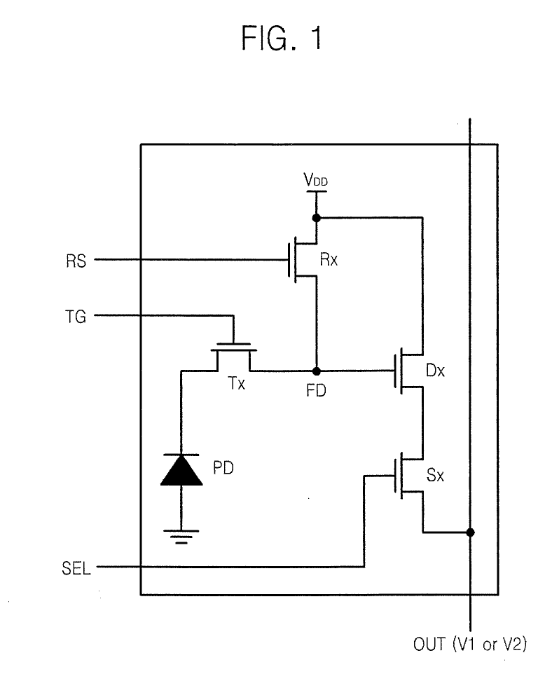

A CMOS image sensor according to some embodiments of the present invention will be well described with reference to FIGS. 1 through 4.

FIG. 1 is a circuit diagram of a unit pixel included in a CMOS image sensor according to some embodiments of the present invention. As illustrated in FIG. 1, the unit pixel in the CMOS image sensor includes a photo sensitive device (PSD) which generates an optical charge in response to incident light. The PSD may be include a photo diode (PD), a photo transistor, a photo gate, a pinned photo diode (PPD) or a combination thereof. For purposes of explanation only, it is assumed that the PSD includes a PD, although the present invention is not restricted thereto.

The unit pixel in the CMOS image sensor can include a transfer transistor Tx, a reset transistor Rx, a drive transistor Dx, and a select transistor Sx. The transfer transistor Tx selectively transfers a charge generated by the PD to a floating diffusion region FD. The reset transistor Rx repetitively (e.g., periodically) resets a charge stored in the floating diffusion region FD to a defined level. The drive transistor Dx is configured as a source follower buffer amplifier that buffers a signal corresponding to the charge in the floating diffusion region FD. The select transistor Sx is configured to perform switching and addressing that selects the unit pixel. In FIG. 1, “RS” refers to a signal applied to a gate of the reset transistor Rx and “TG” refers to a signal applied to a gate of the transfer transistor Tx.

The unit pixel illustrated in FIG. 1 includes a single PD and four MOS transistors Tx, Rx, Dx, and Sx, however the present invention is not restricted thereto, as any number of PDs and transistors may be used. For example, a unit pixel in a CMOS image sensor may include a transfer transistor Tx, a source follower buffer amplifier in a transistor region, and a PD.

The exemplary unit pixel in a CMOS image sensor may operate as follows. The reset transistor Rx, the transfer transistor Tx, and the select transistor Sx can be turned on so as to reset the unit pixel. When the unit pixel is reset, accumulated charge from the PD is depleted and can then accumulate again in response to incident light. The amount of charge that is accumulated at the floating diffusion region FD is proportion to a supply voltage V_{DD}.

Thereafter, the transfer transistor Tx can be turned off (cycled off) and the select transistor Sx can be turned on (cycled on), and, then, the reset transistor Rx can be turned off (cycled off). A first output voltage V₁ is read from an output terminal OUT of the unit pixel and stored in a buffer. Thereafter, the transfer transistor Tx is turned on so that the charges generated at the PD in response to intensity of incident light are moved to the floating diffusion region FD. Next, a second output voltage V₂ is read from the output terminal OUT and analog data corresponding to a voltage difference V₁−V₂ is converted into digital data, which may complete an operating detection cycle of the unit pixel.

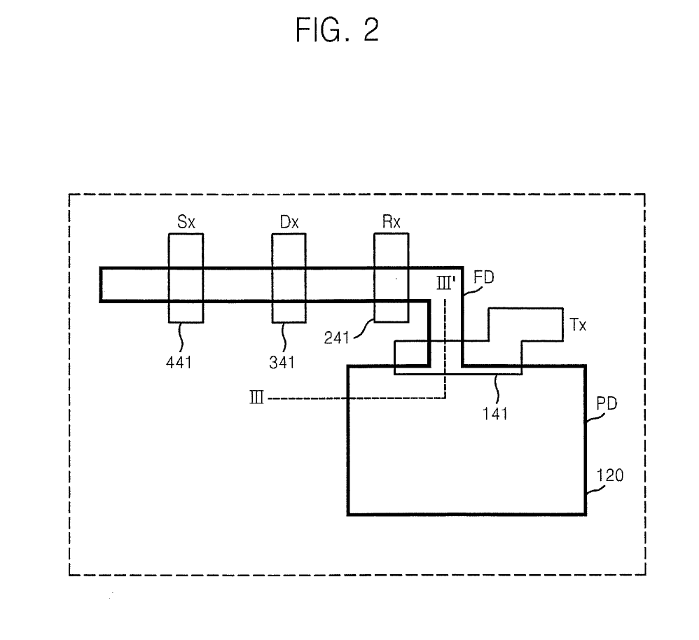

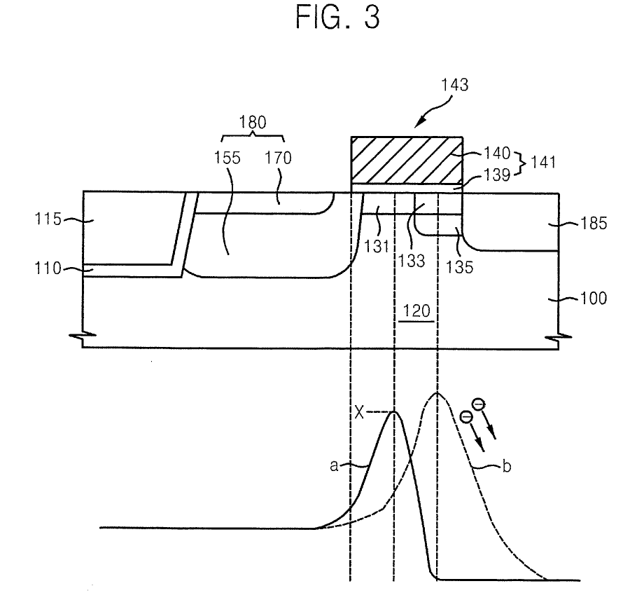

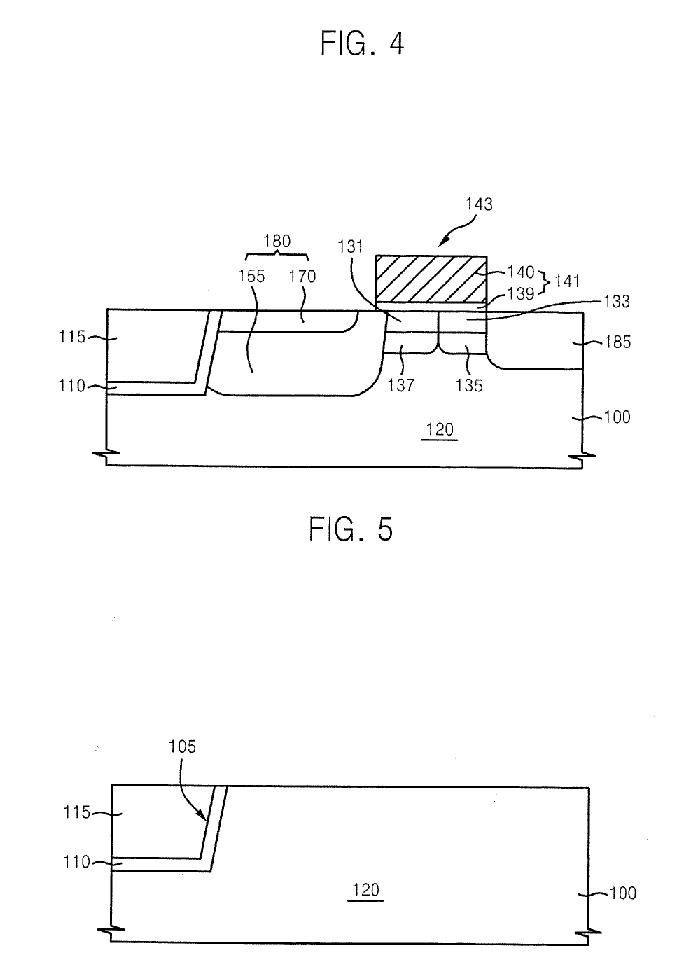

The CMOS image sensor is described in more detail with reference to FIGS. 2 through 4. FIG. 2 illustrates a layout of a unit pixel included in a CMOS image sensor according to some embodiments of the present invention. FIGS. 3 and 4 are cross-sectional views of the unit pixel taken along the line III-III′ illustrated in FIG. 2.

Referring to FIG. 2, in the unit pixel included in the CMOS image sensor, an active region 120 is illustrated by a bold solid line and a device isolation region (115 in FIG. 3) is illustrated outside the active region 120. The illustrated device isolation region 115 may be formed using a shallow trench isolation (STI) process, or may be formed using a local oxidation of silicon (LOCOS) process.

A gate 141 of a transfer transistor Tx, a gate 241 of a reset transistor Rx, a gate 341 of a drive transistor Dx, and a gate 441 of a select transistor Sx are disposed crossing an upper portion of the active region 120.

Various further embodiments of the CMOS image sensor are described below. Referring to FIG. 3, the CMOS image sensor includes a semiconductor substrate 100 having the device isolation region 115 and the active region 120. The semiconductor substrate 100 may be a silicon based substrate or other conventional microelectronic substrates may be used.

The device isolation region 115 may be surrounded by a channel stop region 110. The channel stop region 110 may be a P-type impurity doped region, for example, a boron (B) doped region. The channel stop region 110 may function to reduce/eliminate dark current, which may otherwise be formed at a heterointerface between the semiconductor substrate 100 and the device isolation region 115, and may also function to reduce/eliminate a parasitic signal path between the device isolation region 115 and the adjacent active region 120.

A PD 180 is disposed in the semiconductor substrate 100 adjacent to the device isolation region 115. The PD 180 can include an N-type PD region 155 and a P-type PD region 170. The N-type PD region 155 may at least partially extend underneath the transfer gate 141 (FIG. 2), which may function to reduce/eliminate an afterimage of the CMOS image sensor.

The P-type PD region 170 is disposed on the N-type PD region 155, and may function to reduce dark current at an upper surface of the PD 180 which may contain a relatively large amount of dangling bonds. More particularly, in electron-hole pairs that are thermally generated as dangling bonds on the upper surface of the semiconductor substrate 100, the holes may be diffused to the grounded substrate through the P-type PD region 170 and the electrons may recombine with holes and be eliminated while being diffused to the P-type PD region 170. As a result, the thermally generated electrons may be inhibited/prevented from being accumulated at the N-type PD region 155, which may reduce the level of dark current.

In addition, the transfer gate 141 of the transfer transistor 143 functions to transfer charges that are generated by the PD 180 to a floating diffusion region 185 which is disposed in the semiconductor substrate 100. The transfer gate 141 includes a gate insulation film 139 and a gate electrode 140. The gate insulation film 139 may include silicon oxide or silicon nitride. The gate electrode 140 may include polysilicon, tungsten (W), titanium nitride (TiN), tantalum (Ta), tantalum nitride (TaN), or a combination thereof.

A P-type first impurity region 131 is in the semiconductor substrate 100 below the transfer gate 141, adjacent to a side of the PD 180, and spaced apart from the floating diffusion region 185. An N-type second impurity region 133 is in the semiconductor substrate 100 below the transfer gate 141, and is between the P-type first impurity region 131 and the floating diffusion region 185. The N-type second impurity region 133 and the P-type first impurity region 131 may extend the same depth away from an upper surface of the substrate 100 underneath the transfer gate 141. A P-type third impurity region 135 is in the semiconductor substrate 100 located below the N-type second impurity region 133 and adjacent to the floating diffusion region 185. The P-type third impurity region 135 is separated from the PD 180 by the P-type first impurity region 131.

The P-type first impurity region 131 and the N-type second impurity region 133, which are below the transfer gate 141, are configured so that a peak “x” of a potential barrier “a” of the transfer gate 141 is adjacent to the PD 180, as shown in FIG. 3. As a result, electrons that are generated in a channel region of the transfer transistor 143 are inhibited from flowing into the PD 180 and instead flow to the floating diffusion region 185, which may greatly reduce the level of dark current while no/low light energy is incident to the PD 180. A dotted line “b” shown in FIG. 3 indicates a relative location of a potential barrier in a conventional CMOS image sensor.

To reduce/prevent a blooming effect in which an excessive level of captured photoelectrons overflow to an adjacent PD, the electrons generated at the PD 180 can be more easily discharged to the floating diffusion region 185 by lowering the potential barrier “a” of the transfer gate 141. As described above, when the third impurity region 135 is disposed below the second impurity region 133, the peak “x” of the potential barrier “a” of the transfer gate 141 is decreased, which may reduce/prevent the blooming effect.

Thus, excessive photoelectrons captured in the PD 180 may more easily flow to the floating diffusion region 185, and electrons that remain in the channel region of the transfer transistor 143 may be discharged to the floating diffusion region 185. In particular, because the potential barrier “a” of the transfer gate 141 has a sharp slope between the channel region and the floating diffusion region 185, electrons remaining in the channel region may escape more easily to the floating diffusion region 185. As a result, dark current may be further reduced/eliminated.

Referring to FIG. 4, an N-type fourth impurity region 137 may be formed in the semiconductor substrate 100 below the first impurity region 131, and between the N-type PD region 155 and the P-type third impurity region 135. The N-type fourth impurity region 137 may function to further reduce/eliminate the blooming effect.

Methods of fabricating CMOS image sensors according to some embodiments of the present invention are described below with reference to FIGS. 5 through 11, which are cross-sectional views of sequential stages of the exemplary methods.

Referring to FIG. 5, a trench 105 is formed in the semiconductor substrate 100, which may be a P-type silicon substrate, to define a location of the active region 120 of the semiconductor substrate 100. The channel stop region 110 may be selectively formed on the inner wall and the bottom of the trench 105. The channel stop region 110 may be formed using P-type impurity ions. For example, the channel stop region 110 may be formed by introducing boron (B) having a concentration of 10¹² to 10¹³ ions/cm² into the trench 105. The trench 105 is then filled with an insulation material to form the device isolation region 115, and to further define the active region 120.

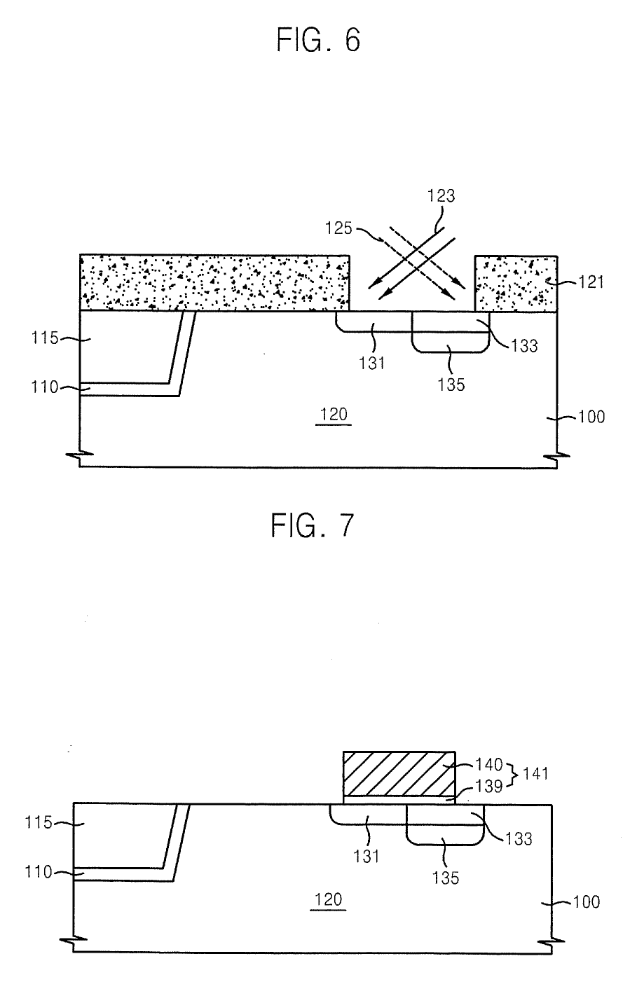

Referring to FIG. 6, a first mask pattern 121 is formed on the semiconductor substrate 100 with an opening that exposes a region of the substrate 100 where the transfer gate 141 (FIG. 3) and/or a channel region of the transfer transistor 143 (FIG. 3) will be formed on the active region 120. Thereafter, P-type impurity ions, e.g., boron (B) ions are implanted in a first direction 123 into the semiconductor substrate 100 exposed through the first mask pattern 121, thereby forming the P-type first impurity region 131 in the semiconductor substrate 100. The P-type impurity ions may be implanted at an energy allowing the P-type first impurity region 131 to extend from a surface of the semiconductor substrate 100 down a defined depth. In addition, when forming the first impurity region 131, the tilt angle of the first direction 123 may be adjusted to generate a shading region, where impurity ions do not reach because the semiconductor substrate 100 is partially shaded by the first mask pattern 121. The tilt angle may be in a range between 10 degrees and 45 degrees. Alternatively or additionally, the thickness of the first mask pattern 121 may be adjusted to vary the amount of shading provided by the first mask pattern 121 to the exposed semiconductor substrate 100 when the impurity ions are implanted into the first impurity region 131. Accordingly, the first impurity region 131 is formed in only a portion of the exposed semiconductor substrate 100.

Next, N-type impurity ions, e.g., phosphorous (P) ions are implanted in a second direction 125 in the semiconductor substrate 100 exposed through the first mask pattern 121, thereby forming the N-type second impurity region 133 in a portion of the exposed semiconductor substrate 100. The second direction 125 and the first direction 123 may be in reflection symmetry. The N-type impurity ions may be implanted at an energy level allowing the second impurity region 133 to extend from a surface of the semiconductor substrate 100 down to a defined depth, where the defined depth may be the same as that formed for the first impurity region 131. When forming the second impurity region 133, the tilt angle of the second direction 125 may be adjusted to vary the length of a region shaded by the first mask pattern 121. The tilt angle of the second direction 125 may be in a range between 135 degrees and 170 degrees. Alternatively or additionally, the thickness of the first mask pattern 121 may be adjusted to vary the amount of shading provided by the first mask pattern 121 to the exposed semiconductor substrate 100 when the impurity ions are implanted into the second impurity region 133. Accordingly, the second impurity region 133 is formed in only a portion of the exposed semiconductor substrate 100.

Thereafter, the P-type third impurity region 135 may be formed below the second impurity region 133. As the second impurity region 133 is formed, P-type impurity ions, e.g., boron (B) ions are implanted in the second direction 125 using the first mask pattern 121 as an ion implantation mask, thereby forming the third impurity region 135 below the second impurity region 133. The P-type impurity ions may be implanted with a higher energy level along the second direction 125 than an energy level with which the N-type impurity ions were implanted along the second direction 125, so that the third impurity region 135 is formed at a greater depth in the semiconductor substrate 100 than the second impurity region 133. The tilt angle of the second direction 125 may also be adjusted to define a length of a region that is shaded by the first mask pattern 121. The tilt angle of the second direction 125 may be in a range between 135 and 170 degrees while the third impurity region 135 is formed. Accordingly, the third impurity region 135 is formed in only a portion of the exposed semiconductor substrate 100.

Although the second impurity region 133 has been described as being formed before the third impurity region 135, the present invention is not restricted thereto. Instead, the third impurity region 135 may be formed before the second impurity region and/or before the first impurity region is formed in the semiconductor substrate 100. In other embodiments, the first impurity region 131, the second impurity region 133, and the third impurity region 135 may be formed in yet other orders relative to each other.

Referring to FIG. 7, the first mask pattern 121 illustrated in FIG. 6 is removed and then a gate oxide film (not shown) and a gate conductive layer (not shown) are formed on the semiconductor substrate 100. Next, a predetermined mask pattern (not shown) is formed on the gate oxide film and the gate conductive layer. The gate oxide film and the gate conductive layer are patterned using the predetermined mask pattern as an etch mask, thereby forming the transfer gate 141, the reset gate 241 (FIG. 2), the drive gate 341 (FIG. 2), and the select gate 441 (FIG. 2). Only the transfer gate 141 is illustrated in FIG. 7. The transfer gate 141 includes the gate insulation film 139 and the gate electrode 140.

The transfer gate 141 at least partially overlaps the first impurity region 131, the second impurity region 133, and the third impurity region 135. Accordingly, the first impurity region 131, the second impurity region 133, and the third impurity region 135 are at least partially below the transfer gate 141.

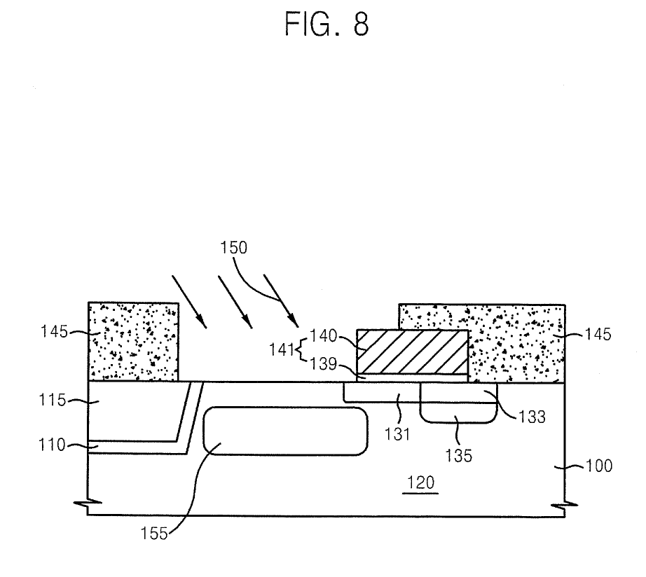

Referring to FIG. 8, a second mask pattern 145 is formed to expose the active region 120 of the semiconductor substrate 100 between the transfer gate 141 and the device isolation region 115. Subsequently, N-type impurity ions, e.g., phosphorous (P) ions are implanted in the semiconductor substrate 100 using the second mask pattern 145 as an ion implantation mask, thereby forming the N-type PD region 155. The N-type PD region 155 may be formed so as to extend at least partially underneath the transfer gate 141, which may reduce/eliminate an afterimage of the CMOS image sensor. To form the N-type PD region 155 extending at least partially underneath the transfer gate 141, the N-type impurity ions may be implanted in a third direction 150 having a predetermined tilt angle with respect to the semiconductor substrate 100. The tilt angle can be regulated so as to control the location of the N-type PD region 155, and the distance it extends under the transfer gate 141.

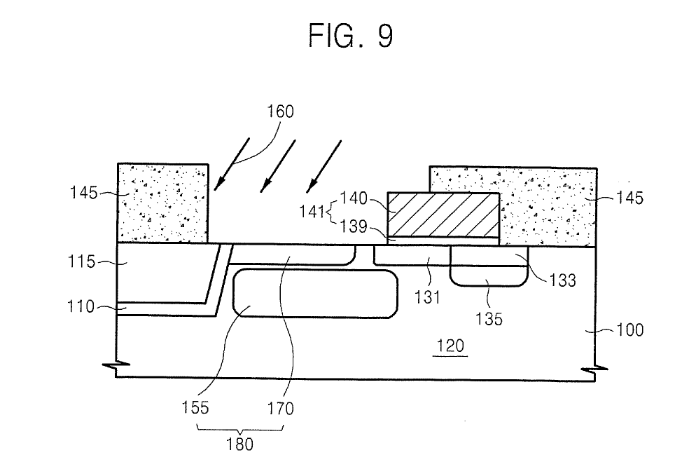

Referring to FIG. 9, P-type impurity ions, e.g., boron (B) ions, are implanted in the semiconductor substrate 100, using the second mask pattern 145 as an ion implantation mask, to form the P-type PD region 170 above the N-type PD region 155. The P-type impurity ions may be implanted in a fourth direction 160 having a predetermined tilt angle with respect to a surface of the semiconductor substrate 100 so that the P-type impurity ions are implanted to a defined depth in a region adjacent to the device isolation region 115. To form the P-type PD region 170 lower in the semiconductor substrate 100 than the N-type PD region 155, the P-type impurity ions are implanted at a lower energy level than the energy level used to form the N-type PD region 155. Reference numeral 180 collectively refers to the PD including the N-type PD region 155 and the P-type PD region 170.

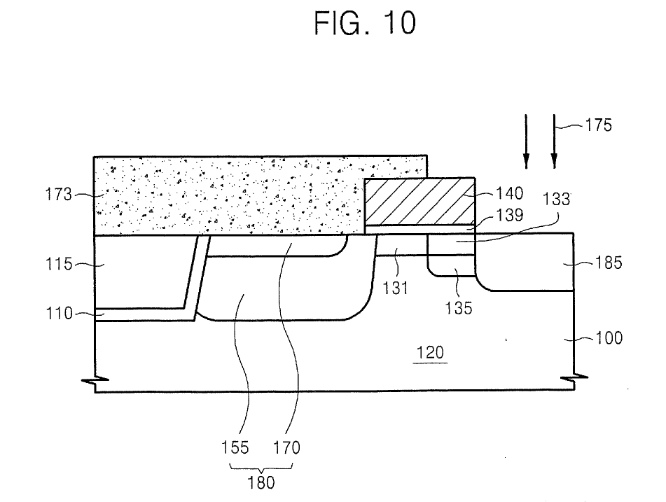

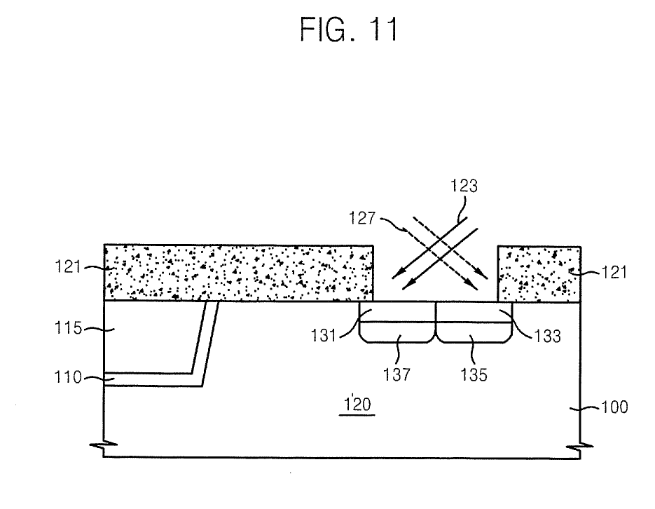

Referring to FIG. 10, the second mask pattern 145 illustrated in FIG. 9 is removed. A third mask pattern 173 is formed on the semiconductor substrate 100, and has an opening that exposes a portion of the transfer gate 141 and, more particularly, exposes a region where the floating diffusion region 185 will be formed. N-type impurity ions, e.g., phosphorous (P) ions, are implanted in the semiconductor substrate 100 in a substantially perpendicular direction 175 using the third mask pattern 173 as an ion implantation mask, thereby forming the floating diffusion region 185.

Each impurity region is then activated and a wiring process is performed using conventional processes to complete the CMOS image sensor.

An N-type fourth impurity region 137 may be formed below the transfer gate 141 as illustrated in FIG. 4, by implanting N-type impurity ions, e.g., phosphorous (P) ions, below the first impurity region 131 using the first mask pattern 121 as an ion implantation mask, as illustrated in FIG. 11. The N-type impurity ions are implanted at a higher energy level than the P-type impurity ions implanted into the first impurity region so that the fourth impurity region 137 is formed at a greater depth in the semiconductor substrate 100 than the first impurity region 131. In the same manner as that used when forming the first impurity region 131, the N-type impurity ions may be implanted in the first direction 123 at a predetermined tilt angle in a range between, for example, 10 degrees and 45 degrees. As described above, shading region occurs due to the first mask pattern 121 and the tilt angle, and therefore, the fourth impurity region 137 is formed in only a portion of the exposed semiconductor substrate 100. The associated remaining processes have been described above, and accordingly the redundant description thereof will be omitted.

As described above, some embodiments of the present invention may reduce/prevent dark current and/or the blooming effect, which may improve the operational characteristics of the CMOS image sensor.

While the present invention has been shown and described with reference to exemplary embodiments thereof, it will be understood by those of ordinary skill in the art that various changes in form and detail may be made herein without departing from the spirit and scope of the present invention, as defined by the following claims.

What is claimed is:

1. A method of fabricating a CMOS image sensor, the method comprising:
forming a first impurity region having a first conductivity type in a semiconductor substrate;
forming a second impurity region having a second conductivity type in the semiconductor substrate adjacent to the first impurity region;
forming a third impurity region having the first conductivity type in the semiconductor substrate and below the second impurity region;
forming a transfer gate on the semiconductor substrate and at least partially overlying the first, second, and third impurity regions;
forming a photo sensitive device in the semiconductor substrate and adjacent to a side of the transfer gate; and
forming a floating diffusion region in the semiconductor substrate and adjacent to an opposite side of the transfer gate from the photosensitive device.

2. The method of claim 1, wherein:
the photosensitive device is formed in the semiconductor substrate adjacent to the first impurity region; and
the floating diffusion region is formed in the semiconductor substrate adjacent to the second and third impurity regions.

3. The method of claim 1, wherein the first conductivity type is one of a P-type and an N-type and the second conductivity type is the other one of the P-type and the N-type.

4. The method of claim 1, wherein formation of the first, second, and third impurity regions comprises:
forming an ion implantation mask on an upper surface of the semiconductor substrate and having an opening that exposes a region of the semiconductor substrate;
forming the first impurity region by implanting impurity ions having the first conductivity type into the semiconductor substrate at a first tilt angle through the opening in the ion implantation mask;
forming the second impurity region by implanting impurity ions having the second conductivity type into the semiconductor substrate at a second tilt angle through the opening in the ion implantation mask; and
forming the third impurity region by implanting impurity ions having the first conductivity type into the semiconductor substrate below the second impurity region at a third tilt angle through the opening in the ion implantation mask.

5. The method of claim 4, wherein the first tilt angle is in a range between 10 degrees and 45 degrees with respect to the upper surface of the semiconductor substrate.

6. The method of claim 4, wherein the second and third tilt angles are in a range between 135 degrees and 170 degrees with respect to the upper surface of the semiconductor substrate.

7. The method of claim 4, wherein the first, second, and third tilt angles and a thickness of the ion implantation mask are defined so that the first impurity region is formed adjacent to the second impurity region in the semiconductor substrate.

8. The method of claim 1, wherein the first and second impurity regions are formed to extend downward from an upper surface of the semiconductor substrate.

9. The method of claim 1, wherein the second impurity region is between the first impurity region and the floating diffusion region, and the first impurity region is between the second impurity region and the photo sensitive device.

10. The method of claim 1, further comprising forming a fourth impurity region having the second conductivity type, and which is below the first impurity region and the transfer gate and is adjacent to the photo sensitive device.

11. The method of claim 10, wherein formation of the fourth impurity region comprises implanting impurity ions having the first conductivity type at a third tilt angle through the opening in the ion implantation mask into a region of the semiconductor substrate below the first impurity region.

12. The method of claim 11, wherein the fourth tilt angle is in a range between 10 degrees and 45 degrees with respect to an upper surface of the semiconductor substrate.

13. The method of claim 10, wherein the fourth impurity region is formed at the same depth in the semiconductor substrate as the third impurity region.

14. The method of claim 10, wherein the third impurity region is formed between the fourth impurity region and the floating diffusion region.
